(19) United States
(12) Patent Application Publication
(10) Pub. No.: US 2025/0240184 A1
(43) Pub. Date: Jul. 24, 2025

(54) METHOD AND APPARATUS FOR SUPPRESSING RINGING IN CONTROLLER AREA NETWORK (CAN) BUS

(71) Applicant: Microchip Technology Incorporated, Chandler, AZ (US)

(72) Inventors: Declan Jordan, Skerries (IE); David Gammie, Chandler, AZ (US)

(73) Assignee: Microchip Technology Incorporated, Chandler, AZ (US)

(21) Appl. No.: 18/986,396

(22) Filed: Dec. 18, 2024

Related U.S. Application Data
(60) Provisional application No. 63/611,662, filed on Dec. 18, 2023.

(51) Int. Cl. H04L 12/40; H04L 12/10

(52) U.S. Cl. CPC H04L 12/40; H04L 12/10; H04L 2012/40215

(57) ABSTRACT

A circuit to suppress ringing in a Controller Area Network (CAN) bus having a CAN high (CANH) wire and a CAN low (CANL) wire is provided. The circuit may include processing circuitry to generate a CAN control signal, and a transconductance amplifier to receive a first input signal corresponding to the CAN control signal and a voltage signal from the CANL wire, and to generate an output current signal based on a difference between the first input signal and the voltage signal from the CANL wire. An output terminal of the transconductance amplifier may be coupled to the CANH wire to source current to or sink current from the CANH wire.

### CROSS REFERENCE TO RELATED APPLICATIONS

The present application claims priority to U.S. Provisional Patent Application No. 63/611,662, entitled: Method and Apparatus for Suppressing Ringing in Controller Area Network (CAN) Bus, filed on Dec. 18, 2023, the contents of which are hereby incorporated by reference in their entirety.

### TECHNICAL FIELD

The present disclosure relates generally to driver circuitry for a Controller Area Network (CAN) bus, and more specifically to a method and apparatus for suppressing ringing in the CAN bus caused by mismatched characteristic impedance.

### SUMMARY

According to an aspect of one or more examples, there is provided a circuit to suppress ringing in a Controller Area Network (CAN) bus having a CAN high (CANH) wire and a CAN low (CANL) wire. The circuit may include processing circuitry to generate a CAN control signal, and a transconductance amplifier to receive a first input signal corresponding to the CAN control signal and a voltage signal from the CANL wire, and to generate an output current signal based on a difference between the first input signal and the voltage signal from the CANL wire. An output terminal of the transconductance amplifier may be coupled to the CANH wire to source current to or sink current from the CANH wire. The circuit may also include a CAN low driver coupled to the processing circuitry, ground or a common node, and the CANL wire of the CAN bus, a CAN high driver coupled to the processing circuitry, a supply voltage, and the CANH wire of the CAN bus, and a terminating resistor coupled between the CANH wire and the CANL wire of the CAN bus. The CAN low driver may be coupled to a circuit simulating CAN bus ringing via the CANL wire of the CAN bus, and the CAN high driver may be coupled to the circuit simulating CAN bus ringing via the CANH wire of the CAN bus.

The transconductance amplifier may receive a gain control signal to control a gain of the transconductance amplifier, and the output current signal may be generated based on the gain control signal. The gain control signal may correspond to a ratio of a first current signal corresponding to an exponential function and a second current signal corresponding to a hyperbolic function. The exponential function may be e^{x} and the hyperbolic function may be cosh(x), where x is an input voltage of the CAN bus. The gain control signal may be equivalent to the CAN control signal. The circuit may also include converting circuitry to convert current signals to voltage signals. The CAN control signal may be a signal corresponding to a ratio of a first current signal corresponding to an exponential function and a second current signal corresponding to a hyperbolic function and the converting circuitry may convert the CAN control signal to a voltage signal that is input to the transconductance amplifier as the first input signal. The exponential function may be e^{x} and the hyperbolic function may be cosh(x), where x is an input voltage to the CAN bus.

According to an aspect of one or more examples, there is provided a method of suppressing ringing in a Controller Area Network (CAN) bus having a CAN high (CANH) wire and a CAN low (CANL) wire. The method may include generating a CAN control signal, receiving a first input signal corresponding to the CAN control signal and a voltage signal from the CANL wire, generating an output current signal based on a difference between the first input signal and the voltage signal from the CANL wire, and sourcing current to or sinking current from the CANH wire based on the output current signal. The method may also include receiving a gain control signal, and the output current signal may be generated based on the gain control signal. The gain control signal may correspond to a ratio of a first current signal corresponding to an exponential function and a second current signal corresponding to a hyperbolic function. The exponential function may be e^{x} and the hyperbolic function may be cosh(x), where x is an input voltage of the CAN bus. The gain control signal may be equivalent to the CAN control signal. The CAN control signal may be a current signal corresponding to a ratio of a first current signal corresponding to an exponential function and a second current signal corresponding to a hyperbolic function and the method may include converting the CAN control signal to a voltage signal that is received as the first input signal. The exponential function may be e^{x} and the hyperbolic function may be cosh(x), where x is an input voltage of the CAN bus.

### BRIEF DESCRIPTION OF DRAWINGS

FIG. 1 shows a circuit diagram of a circuit to suppress ringing in a Controller Area Network (CAN) bus according to various examples.

FIG. 2 shows a circuit diagram of a CAN low (CANL) driver according to FIG. 1.

FIG. 3 shows a circuit diagram of a CAN high (CANH) driver according to FIG. 1.

FIG. 4 shows a circuit diagram of a transconductance amplifier according to FIG. 1.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

CAN buses are used in a variety of applications to allow multiple devices to communicate with each other using a common bus. Perhaps the most common use of CAN buses is in automobiles to allow various controllers, processors, sensors, and other devices to transmit and receive information using a single bus. A CAN bus is made of two wires, a CAN low (CANL) wire and a CAN high (CANH) wire, and a differential signal is created between the two wires.

CAN buses are often driven by a current waveform. Characteristic impedance mismatching in the CAN bus can result in ringing as the current through the CAN bus oscillates between parasitic inductance and capacitance. The ringing may be particularly noticeable during transitions in the waveform. Therefore, there is a need to suppress ringing in the CAN bus.

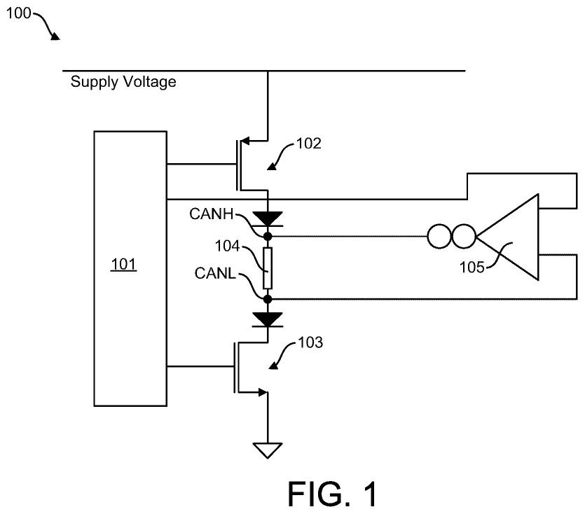

FIG. 1 shows a circuit diagram of a circuit 100 to suppress ringing in a CAN bus according to various examples. The circuit 100 of FIG. 1 may include processing circuitry 101, such as, without limitation, a general or specific-purpose processor, microprocessor, controller, or microcontroller, to generate a CAN control waveform. The processing circuitry 101 may be coupled to a CANH driver 102, which is coupled to a supply voltage and the CANH wire of the CAN bus. The processing circuitry 101 may also be coupled to a CANL driver 103, which is coupled to ground or a common node and the CANL wire of the CAN bus. A terminating resistor 104 is coupled between the CANH wire and the CANL wire of the CAN bus.

According to various examples, the processing circuitry 101 may receive an input voltage x and may generate a CAN control signal based on the received input voltage x. According to various examples, the CAN control signal may be a current signal or a voltage signal. According to various examples, the CAN control signal may correspond to a ratio of a first signal corresponding to an exponential function (e.g., e^{x}) and a second current signal corresponding to a hyperbolic function (e.g., cosh(x)). However, various examples may generate other CAN control voltage or current signals.

The circuit 100 of FIG. 1 may also include an operational transconductance amplifier 105 having a first input to receive the CAN control signal from the processing circuitry 101. According to various examples in which the CAN control signal is a voltage signal, the CAN control voltage signal may be input to the first input of the operational transconductance amplifier 105. According to various examples in which the CAN control signal is a current signal, for example, a current signal corresponding to a ratio of a first current signal corresponding to an exponential function (e.g., e^{x}) and a second current signal corresponding to a hyperbolic function (e.g., cosh(x)), circuitry to convert a current signal to a voltage signal, such as a diode-connected transistor discussed further below, may be used to convert the CAN control current signal to a corresponding voltage signal.

The operational transconductance amplifier 105 of FIG. 1 may also have a second input to receive a voltage signal from the CANL wire of the CAN bus. The operational transconductance amplifier 105 may generate an output current signal based on the difference between the CAN control signal and the voltage signal from the CANL wire. According to various examples, the operational transconductance amplifier 105 may receive a gain control signal to control the gain of the operational transconductance amplifier 105. For example, the gain control signal may be the CAN control signal such that the gain of the operational transconductance amplifier 105 may be proportional to the CAN control signal. The generated output current signal may be provided to the CANH wire of the CAN bus to source or sink current at the CANH driver stage. By sourcing or sinking current to or from the CANH driver stage that is proportional to the difference between the CAN control signal and the voltage signal of the CANL wire, the output current signal may destructively interfere with the current oscillation between parasitic capacitance and inductance on the CAN bus to suppress ringing.

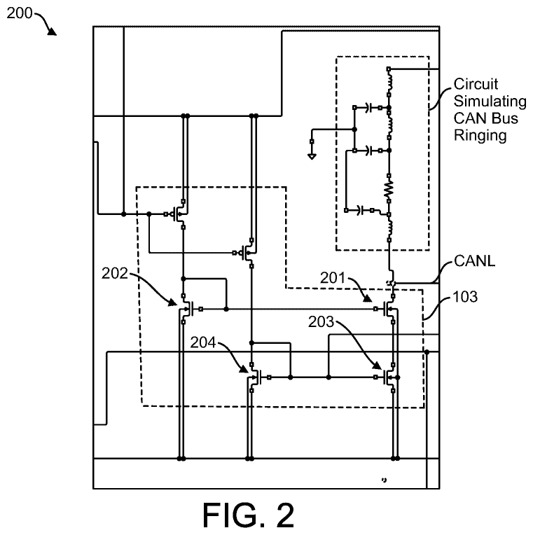

FIG. 2 shows a circuit diagram 200 of the CANL driver 103 according to FIG. 1, which contains a number of components, some of which will not be discussed in detail here to avoid obscuring other aspects of the circuit. As shown in FIG. 2, the CANL driver 103 may include a first field-effect transistor (FET) 201, the drain terminal of which may be coupled to the CANL wire of the CAN bus and a circuit used to simulate CAN bus ringing. A second FET 202 may form a current mirror with the first FET 201, and third and fourth FETs 203 and 204 may form another current mirror. The CANL signal may be a voltage signal that is output from the drain terminal of the first FET 201 to the transconductance amplifier 105, as explained below.

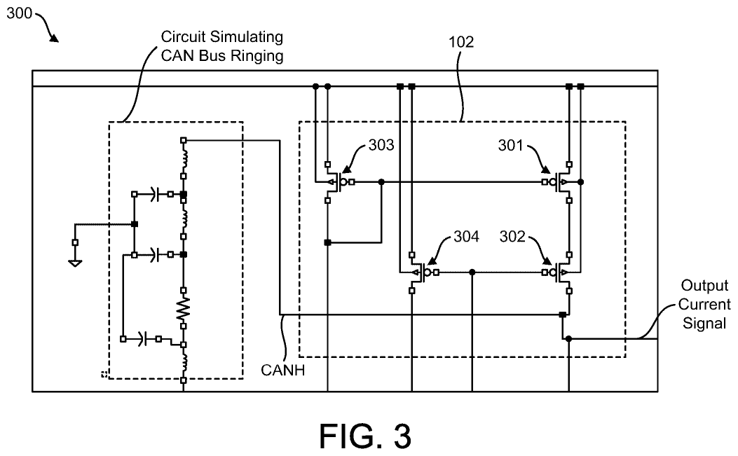

FIG. 3 shows a circuit diagram 300 of the CANH driver 102 according to FIG. 1, which contains a number of components, some of which will not be discussed in detail here to avoid obscuring other aspects of the circuit. As shown in FIG. 3, the CANH driver 102 may include first, second, third, and fourth FETs 301, 302, 303, and 304. The first and third FETs 301, 303 may form a current mirror, with the first FET 301 coupled to the second FET 302. The drain terminal of the second FET 302 may be coupled to the CANH wire, and may also receive the output current signal from the transconductance amplifier 105, as explained further below. FIG. 3 shows an example circuit to simulate ringing on the CAN bus, which may also be coupled to the drain terminal of the second FET 302.

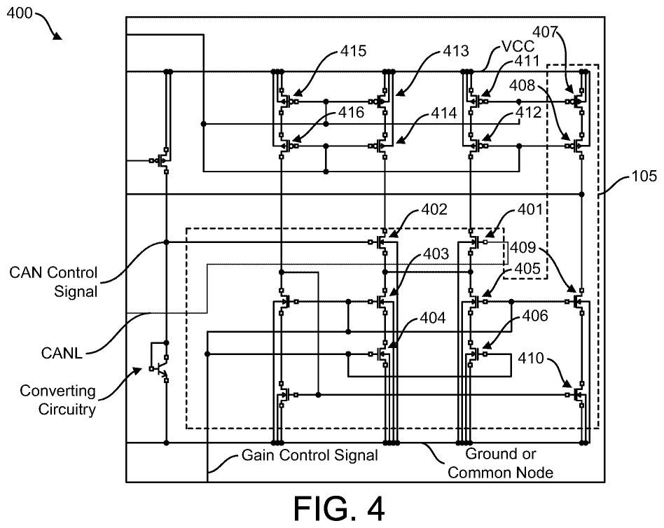

FIG. 4 shows a circuit diagram 400 of the transconductance amplifier 105 according to FIG. 1, which contains a number of components, some of which will not be discussed in detail here to avoid obscuring other aspects of the circuit. As shown in FIG. 4, the transconductance amplifier 105 may include a first FET 401 to receive at its gate terminal a voltage signal from the CANL wire. The transconductance amplifier 105 may also include a second FET 402 to receive at its gate terminal the CAN control signal from processing circuitry for generating the CAN control signal 101 (not shown). For example, the processing circuitry for generating the CAN control signal 101 may generate a current signal corresponding to a ratio of a first current signal corresponding to an exponential function (e.g., e^{x}) and a second current signal corresponding to a hyperbolic function (e.g., cosh(x), where x is an input voltage provided to the CAN bus). For example, the first current signal corresponding to an exponential function (e.g., e^{x}) and the second current signal corresponding to a hyperbolic function (e.g., cosh(x)) may be generated by translinear loop circuits.

The transconductance amplifier 105 may include converting circuitry, such as a diode connected bi-polar junction transistor (BJT) to convert a CAN control current signal to a corresponding voltage signal. The voltage signal corresponding to the CAN control current signal may be input to the gate terminal of the second FET 402, which together with the first FET 401 may form a differential input of the transconductance amplifier 105. The transconductance amplifier 105 may include third, fourth, fifth, and sixth FETs 403, 404, 405, and 406, which may receive a gain control signal, and control the gain of the transconductance amplifier 105 based on the gain control signal.

Seventh, eighth, ninth, and tenth FETs 407, 408, 409, and 410 may form an output stage of the transconductance amplifier 105, and may be coupled to the fifth FET 405. Eleventh and twelfth FETs 411 and 412 may be coupled to the first FET 401, which may receive the CANL voltage signal. Thirteenth and fourteenth FETs 413 and 414 may be coupled to the second FET 402, which may receive the CAN control signal. Fifteenth and sixteenth FETs 415 and 416 may be coupled to the eleventh, twelfth, thirteenth, and fourteenth FETs 411, 412, 413, and 414. The eighth and ninth FETs 408 and 409 may output the output current signal to the CANH wire based on the difference between the CAN control signal and the voltage signal from the CANL wire. For example, the seventh and eighth FETs 407 and 408 may be coupled to voltage supply VCC, and may inject current into the CANH wire depending on the difference between the CAN control signal and the voltage signal from the CANL wire. The ninth and tenth FETs 409 and 410 may be coupled to ground or a common node, and therefore may take current from the CANH wire depending on the difference between the CAN control signal and the voltage signal from the CANL wire. The injected or removed current may destructively interfere with current oscillation between parasitic inductance and capacitance to reduce ringing in the CAN bus.

Various examples have been disclosed herein, in connection with the above description and the drawings. It will be understood that it would be unduly repetitious to literally describe and illustrate every combination and subcombination of these examples. Accordingly, all examples can be combined in any way or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A circuit to suppress ringing in a Controller Area Network (CAN) bus having a CAN high (CANH) wire and a CAN low (CANL) wire, the circuit comprising:
processing circuitry to generate a CAN control signal; and
a transconductance amplifier to receive a first input signal corresponding to the CAN control signal and a voltage signal from the CANL wire, and to generate an output current signal based on a difference between the first input signal and the voltage signal from the CANL wire;
wherein an output terminal of the transconductance amplifier is coupled to the CANH wire to source current to or sink current from the CANH wire.

2. The circuit of claim 1, further comprising:
a CAN low driver coupled to the processing circuitry, ground or a common node, and the CANL wire of the CAN bus;
a CAN high driver coupled to the processing circuitry, a supply voltage, and the CANH wire of the CAN bus; and
a terminating resistor coupled between the CANH wire and the CANL wire of the CAN bus.

3. The circuit of claim 2, wherein the CAN low driver is coupled to a circuit simulating CAN bus ringing via the CANL wire of the CAN bus, and the CAN high driver is coupled to the circuit simulating CAN bus ringing via the CANH wire of the CAN bus.

4. The circuit of claim 1, wherein the transconductance amplifier is to receive a gain control signal to control a gain of the transconductance amplifier; and
wherein the output current signal is generated based on the gain control signal.

5. The circuit of claim 4, wherein the gain control signal corresponds to a ratio of a first current signal corresponding to an exponential function and a second current signal corresponding to a hyperbolic function.

6. The circuit of claim 5, wherein the exponential function is e^{x} and the hyperbolic function is cosh(x), where x is an input voltage of the CAN bus.

7. The circuit of claim 4, wherein the gain control signal is equivalent to the CAN control signal.

8. The circuit of claim 1, further comprising:
converting circuitry to convert current signals to voltage signals;
wherein the CAN control signal is a current signal corresponding to a ratio of a first current signal corresponding to an exponential function and a second current signal corresponding to a hyperbolic function; and
wherein the converting circuitry is to convert the CAN control signal to a voltage signal that is input to the transconductance amplifier as the first input signal.

9. The circuit of claim 8, wherein the exponential function is e^{x} and the hyperbolic function is cosh(x), where x is an input voltage to the CAN bus.

10. A method of suppressing ringing in a Controller Area Network (CAN) bus having a CAN high (CANH) wire and a CAN low (CANL) wire, the method comprising:
generating a CAN control signal;
receiving a first input signal corresponding to the CAN control signal and a voltage signal from the CANL wire;
generating an output current signal based on a difference between the first input signal and the voltage signal from the CANL wire; and
sourcing current to or sinking current from the CANH wire based on the output current signal.

11. The method of claim 10, further comprising:
receiving a gain control signal;
wherein the output current signal is generated based on the gain control signal.

12. The method of claim 11, wherein the gain control signal corresponds to a ratio of a first current signal corresponding to an exponential function and a second current signal corresponding to a hyperbolic function.

13. The method of claim 12, wherein the exponential function is e^{x} and the hyperbolic function is cosh(x), where x is an input voltage of the CAN bus.

14. The method of claim 11, wherein the gain control signal is equivalent to the CAN control signal.

15. The method of claim 10, wherein the CAN control signal is a current signal corresponding to a ratio of a first current signal corresponding to an exponential function and a second current signal corresponding to a hyperbolic function; and
wherein the method comprises converting the CAN control signal to a voltage signal that is received as the first input signal.

16. The method of claim of claim 15, wherein the exponential function is e^{x} and the hyperbolic function is cosh(x), where x is an input voltage of the CAN bus.
